(19) United States
(12) Patent Application Publication
(10) Pub. No.: US 2020/0095502 A1
(43) Pub. Date: Mar. 26, 2020

(54) High Oxide VS Nitride Selectivity, Low And Uniform Oxide Trench Dishing In Shallow Trench Isolation(STI) Chemical Mechanical Planarization Polishing(CMP)

(71) Applicant: Versum Materials US, LLC, Tempe, AZ (US)

(72) Inventors: Xiaobo Shi, Chandler, AZ (US); Joseph D. Rose, Gilbert, AZ (US); Krishna P. Murella, Phoenix, AZ (US); Hongjun Zhou, Chandler, AZ (US); Mark Leonard O'Neill, Queen Creek, AZ (US)

(73) Assignee: Versum Materials US, LLC, Tempe, AZ (US)

(21) Appl. No.: 16/577,358

(22) Filed: Sep. 20, 2019

Related U.S. Application Data
(60) Provisional application No. 62/736,963, filed on Sep. 26, 2018.

(51) Int. Cl. C09K 13/06; H01L 21/3105; C09K 13/00; C09G 1/02

(52) U.S. Cl. CPC C09K 13/06; H01L 21/31053; H01L 21/76224; C09G 1/02; C09K 13/00

(57) ABSTRACT

Present invention provides Chemical Mechanical Planarization Polishing (CMP) compositions for Shallow Trench Isolation (STI) applications. The CMP compositions contain ceria coated inorganic oxide particles as abrasives, such as ceria-coated silica particles or any other ceria-coated inorganic oxide particles as core particles; suitable chemical additives comprising at least one organic carboxylic acid group, at least one carboxylate salt group or at least one carboxylic ester group and two or more hydroxyl functional groups in the same molecule; and a water soluble solvent; and optionally biocide and pH adjuster; wherein the composition has a pH of 2 to 12, preferably 3 to 10, and more preferably 4 to 9.

### CROSS-REFERENCE TO RELATED APPLICATIONS

This patent application is a non-provisional of U.S. provisional patent application Ser. No. 62/736,963, filed on Sep. 26, 2018, which is incorporated herein by reference in its entirety.

### BACKGROUND OF THE INVENTION

This invention relates to the STI CMP chemical polishing compositions and chemical mechanical planarization (CMP) for Shallow Trench Isolation (STI) process.

In the fabrication of microelectronics devices, an important step involved is polishing, especially surfaces for chemical-mechanical polishing for the purpose of recovering a selected material and/or planarizing the structure.

For example, a SiN layer is deposited under a SiO₂ layer to serve as a polish stop. The role of such polish stop is particularly important in Shallow Trench Isolation (STI) structures. Selectivity is characteristically expressed as the ratio of the oxide polish rate to the nitride polish rate. An example is an increased polishing selectivity rate of silicon dioxide (SiO₂) as compared to silicon nitride (SiN).

In the global planarization of patterned STI structures, reducing oxide trench dishing is a key factor to be considered. The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

U.S. Pat. No. 5,876,490 discloses the polishing compositions containing abrasive particles and exhibiting normal stress effects. The slurry further contains non-polishing particles resulting in reduced polishing rate at recesses, while the abrasive particles maintain high polish rates at elevations. This leads to improved planarization. More specifically, the slurry comprises cerium oxide particles and polymeric electrolyte, and can be used for Shallow Trench Isolation (STI) polishing applications.

U.S. Pat. No. 6,964,923 teaches the polishing compositions containing cerium oxide particles and polymeric electrolyte for Shallow Trench Isolation (STI) polishing applications. Polymeric electrolyte being used includes the salts of polyacrylic acid, similar as those in U.S. Pat. No. 5,876,490. Ceria, alumina, silica & zirconia are used as abrasives. Molecular weight for such listed polyelectrolyte is from 300 to 20,000, but in overall, <100,000.

U.S. Pat. No. 6,616,514 disclosed a chemical mechanical polishing slurry for use in removing a first substance from a surface of an article in preference to silicon nitride by chemical mechanical polishing. The chemical mechanical polishing slurry according to the invention includes an abrasive, an aqueous medium, and an organic polyol that does not dissociate protons, said organic polyol including a compound having at least three hydroxyl groups that are not dissociable in the aqueous medium, or a polymer formed from at least one monomer having at least three hydroxyl groups that are not dissociable in the aqueous medium.

U.S. Pat. No. 5,738,800 disclosed a composition for polishing a composite comprised of silica and silicon nitride comprising: an aqueous medium, abrasive particles, a surfactant, and a compound which complexes with the silica and silicon nitride wherein the complexing agent has two or more functional groups each having a dissociable proton, the functional groups being the same or different.

WO Patent 2007/086665A1 disclosed a CMP slurry in which a compound having a weight-average molecular weight of 30-500 and containing a hydroxyl group (OH), a carboxyl group (COOH), or both, is added to a CMP slurry comprising abrasive particles and water and having a first viscosity, so that the CMP slurry is controlled to have a second viscosity 5-30% lower than the first viscosity. Also disclosed is a method for polishing a semiconductor wafer using the CMP slurry. According to the disclosed invention, the agglomerated particle size of abrasive particles in the CMP slurry can be reduced, while the viscosity of the CMP slurry can be reduced and the global planarity of wafers upon polishing can be improved. Thus, the CMP slurry can be advantageously used in processes for manufacturing semiconductor devices requiring fine patterns and can improve the reliability and production of semiconductor devices through the use thereof in semiconductor processes.

However, those prior disclosed Shallow Trench Isolation (STI) polishing compositions did not address the importance of oxide trench dishing reducing and more uniform oxide trench dishing on the polished patterned wafers along with the high oxide vs nitride selectivity.

It should be readily apparent from the foregoing that there remains a need within the art for compositions, methods and systems of STI chemical mechanical polishing that can afford the reduced oxide trench dishing and more uniformed oxide trench dishing across various sized oxide trench features on polishing patterned wafers in a STI chemical and mechanical polishing (CMP) process, in addition to high removal rate of silicon dioxide as well as high selectivity for silicon dioxide to silicon nitride.

### BRIEF SUMMARY OF THE INVENTION

The present invention provides for a reduced oxide trench dishing and more uniformed oxide trench dishing across various sized oxide trench features on the polished patterned wafers as well as provides high oxide vs nitride selectivity by introducing chemical additives as SiN film removal rate suppressing agents and oxide trenching dishing reducers in the Chemical mechanical polishing (CMP) compositions for Shallow Trench Isolation (STI) CMP applications at wide pH range including acidic, neutral and alkaline pH conditions.

The disclosed chemical mechanical polishing (CMP) composition for Shallow Trench Isolation (STI) CMP applications have a unique combination of using ceria-coated inorganic oxide particles as abrasives and the suitable chemical additives as oxide trench dishing reducing agents and nitride removal rate suppressing agents.

In one aspect, there is provided a STI CMP polishing composition comprises:

ceria-coated inorganic metal oxide particles;
chemical additive comprising at least one carboxylic acid group (R—COOH), at least one carboxylate salt group(s) or at least one carboxylic ester group; and at least two hydroxyl functional groups (OH) in the same molecule;
a water-soluble solvent; and
optionally
biocide; and
pH adjuster;
wherein the composition has a pH of 2 to 12, preferably 3 to 10, more preferably 4 to 9, and most preferably 4.5 to 7.5.

The ceria-coated inorganic oxide particles include, but are not limited to, ceria-coated colloidal silica, ceria-coated high purity colloidal silica, ceria-coated alumina, ceria-coated titania, ceria-coated zirconia, or any other ceria-coated inorganic metal oxide particles.

The water-soluble solvent includes but is not limited to deionized (DI) water, distilled water, and alcoholic organic solvents.

The chemical additive functions as a SiN film removal rate suppressing agent and oxide trenching dishing reducer.

Some of these chemical additives have a general molecular structure as shown below:

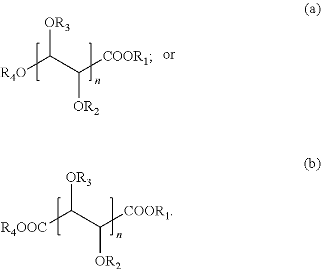

In the general molecular structure (a) or (b), n is selected from 1 to 5,000, the preferred n is from 2 to 12, the more preferred n is from 3 to 6.

R1, R2, R3, and R4 can be the same or different atoms or functional groups. They can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof; wherein, at least two or more, preferably three or more are hydrogen atoms.

In addition, R1, R4, or both R1 and R4 can also be a metal ion or ammonium ion. The metal ion includes but is not limited to sodium ion, potassium ion.

When R1, R2, R3 and R4 are all hydrogen atoms, the chemical additive bears one (structure (a)) or two (structure (b)) organic carboxylic acid groups and two (structure (b)) or more (structure (a)) hydroxyl functional groups.

The molecular structures of some examples of such chemical additives are listed below:

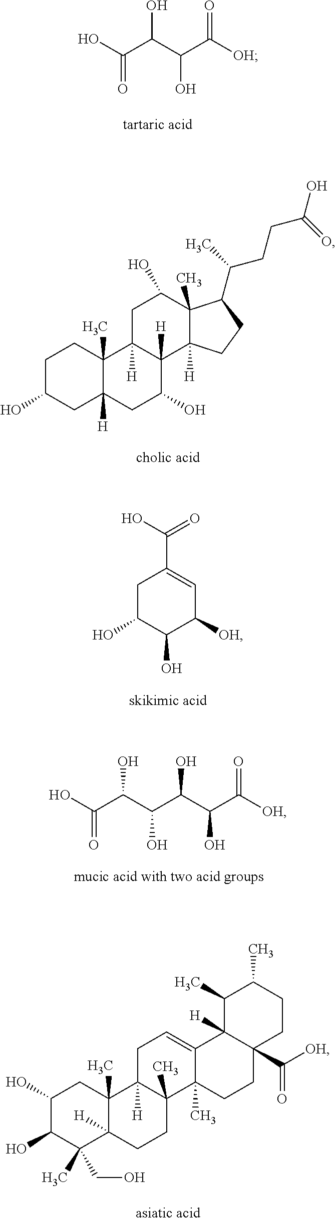

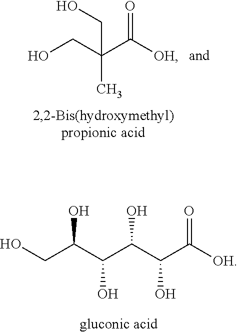

When R1 is a metal ion or ammonium ion in structure (a), the chemical additives have general molecular structures as listed below:

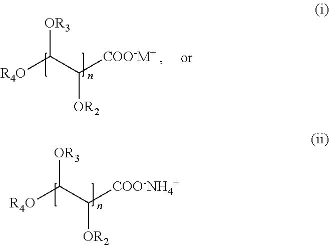

When R1 and R4 are both metal ions or ammonium ions in structure (b), the chemical additives have general molecular structures as listed below:

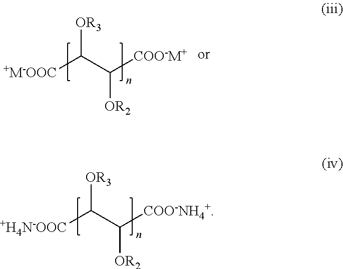

When R 1 is a metal ion and R2, R3, and R4 are all hydrogen atoms in structure (i), the molecular structures of some examples of such chemical additives are listed below:

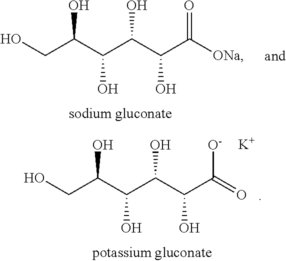

When R1 is an organic alkyl group in structure (a), the chemical additive has the organic acid ester functional group and bearing multi hydroxyl functional groups in the same molecule. The general molecular structure is shown below.

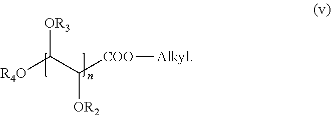

When R2, R3, and R4 are hydrogen atoms in structure (v), the molecular structures of an examples of such chemical additive is shown below:

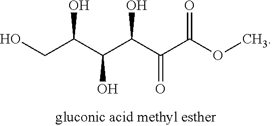 [SMILES: COC(=O)C(=O)[C@H](O)[C@@H](O)[C@H](O)CO]

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished oxide films can be Chemical vapor deposition (CVD), Plasma Enhance CVD (PECVD), High Density Deposition CVD (HDP), or spin on oxide films.

The substrate disclosed above can further comprises a silicon nitride surface. The removal selectivity of SiO₂:SiN is greater than silicon nitride is greater than 25, preferably greater than 30, and more preferably greater than 35.

### BRIEF DESCRIPTION OF SEVERAL VIEWS OF THE DRAWINGS

FIG. 1. Effects of Gluconic Acid on Film RR (Å/min.) & TEOS: SiN Selectivity

FIG. 2. Effects of Gluconic Acid on Oxide Trench Dishing Rate

FIG. 3. Effects of Gluconic Acid on Oxide Trench Loss Rates (A/Sec.)

FIG. 4. Effects of Gluconic Acid on Oxide Trench Dishing vs OP Times (Sec.)

FIG. 5. Effects of Gluconic Acid on Oxide Trench Dishing vs OP Times (Sec.)

FIG. 6. Effects of Gluconic Acid on Oxide Trench Dishing vs OP Times (Sec.)

FIG. 7. Effects of different Gluconic Acid (GA) wt. % on Film RR (Å/min.) & TEOS: SiN Selectivity

FIG. 8. Effects of different Gluconic Acid (GA) wt. % on Oxide Trench Dishing Rate

FIG. 9. Effects of different Gluconic Acid (GA) wt. % on Oxide Trench Loss Rates (A/Sec.)

FIG. 10. Effects of different Gluconic Acid wt. % on Oxide Trench Dishing vs OP Times (Sec.)

FIG. 11. Effects of different Gluconic Acid wt. % on Oxide Trench Dishing vs OP Times (Sec.)

FIG. 12. Effects of different Gluconic Acid wt. % on Oxide Trench Dishing vs OP Times (Sec.)

FIG. 13. Effects of pH and 0.01 wt. % Gluconic Acid (GA) on Film RR (Å/min.) & TEOS: SiN Selectivity

FIG. 14. Effects of pH with 0.01% Gluconic Acid (GA) on Oxide Trench Dishing Rate

FIG. 15. Effects of pH with 0.01% Gluconic Acid (GA) on Oxide Trench Loss Rate

FIG. 16. Effects of pH with 0.01% Gluconic Acid % on Oxide Trench Dishing vs OP Times (Sec.)

FIG. 17. Effects of pH with 0.01% Gluconic Acid % on Oxide Trench Dishing vs OP Times (Sec.)

FIG. 18. Effects of pH with 0.01% Gluconic Acid % on Oxide Trench Dishing vs OP Times (Sec.)

### DETAILED DESCRIPTION OF THE INVENTION

In the global planarization of patterned STI structures, suppressing SiN removal rates and reducing oxide trench dishing and providing more uniform oxide trench dishing across various sized oxide trench features are key factors to be considered. The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

This invention relates to the Chemical mechanical polishing (CMP) compositions for Shallow Trench Isolation (STI) CMP applications.

More specifically, the disclosed chemical mechanical polishing (CMP) composition for Shallow Trench Isolation (STI) CMP applications have a unique combination of using ceria-coated inorganic metal oxide inorganic metal oxide abrasive particles and the suitable chemical additives as oxide trench dishing reducing agents and nitride suppressing agents.

The suitable chemical additives include, but are not limited to organic carboxylic acid molecules, organic carboxylate salts or organic carboxylic ester molecules bearing multi hydroxyl functional groups in the same molecules.

The chemical additives contain at least one organic carboxylic acid group, one carboxylate salt group or one carboxylic ester group and two or more hydroxyl functional groups in the same molecules.

The chemical additives provide the benefits of achieving high oxide film removal rates, low SiN film removal rates, high and tunable Oxide: SiN selectivity, and more importantly, significantly reducing oxide trench dishing and improving over polishing window stability on polishing patterned wafers.

In one aspect, there is provided a STI CMP polishing composition comprises:

ceria-coated inorganic metal oxide particles;
chemical additives as SiN film removal rate suppressing agents and oxide trenching dishing reducers on polishing patterned wafers;
a water-soluble solvent; and
optionally
biocide; and
pH adjuster;
wherein the composition has a pH of 2 to 12, preferably 3 to 10, more preferably 4 to 9, and most preferably 4.5 to 7.5.

The ceria-coated inorganic metal oxide particles include, but are not limited to, ceria-coated colloidal silica, ceria-coated high purity colloidal silica, ceria-coated alumina, ceria-coated titania, ceria-coated zirconia, or any other ceria-coated inorganic metal oxide particles.

The particle sizes (measured by Dynamic Light Scattering DLS technology) of these ceria-coated inorganic metal oxide particles in the disclosed invention herein are ranged from 10 nm to 1,000 nm, the preferred mean particle sized are ranged from 20 nm to 500 nm, the more preferred mean particle sizes are ranged from 50 nm to 250 nm.

The concentrations of these ceria-coated inorganic metal oxide particles range from 0.01 wt. % to 20 wt. %, the preferred concentrations range from 0.05 wt. % to 10 wt. %, the more preferred concentrations range from 0.1 wt. % to 5 wt. %.

The preferred ceria-coated inorganic metal oxide particles are ceria-coated colloidal silica particles.

The preferred chemical additive as SiN film removal rate suppressing agents and oxide trenching dishing reducers comprise at least one carboxylic acid group (R—COOH), at least one carboxylate salt group(s) or at least one carboxylic ester group; and at least two hydroxyl functional groups (OH) in the same molecule;

Some of these chemical additives have a general molecular structure as shown below:

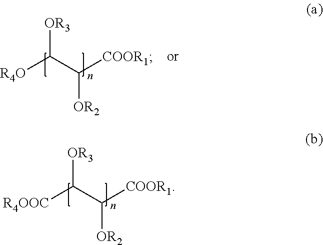

In the general molecular structure (a) or (b), n is selected from 1 to 5,000, the preferred n is from 2 to 12, the more preferred n is from 3 to 6.

R1, R2, R3, and R4 can be the same or different atoms or functional groups. They can be independently selected from the group consisting of hydrogen, alkyl, alkoxy, organic group with one or more hydroxyl groups, substituted organic sulfonic acid, substituted organic sulfonic acid salt, substituted organic carboxylic acid, substituted organic carboxylic acid salt, organic carboxylic ester, organic amine groups, and combinations thereof; wherein, at least two or more, preferably three or more are hydrogen atoms.

In addition, R1, R4, or both R1 and R4 can also be a metal ion or ammonium ion. The metal ion includes but is not limited to sodium ion, potassium ion.

When R1, R2, R3 and R4 are all hydrogen atoms, the chemical additive bears one (structure (a)) or two (structure (b)) organic carboxylic acid groups and two (structure (b)) or more (structure (a)) hydroxyl functional groups.

The molecular structures of some examples of such chemical additives are listed below:

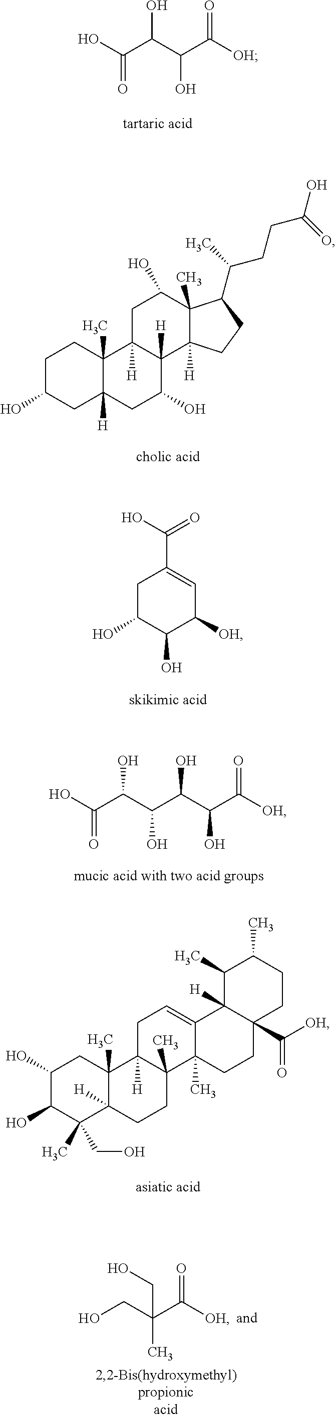

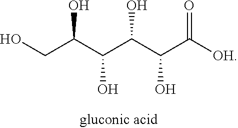 [SMILES: O=C(O)[C@H](O)[C@@H](O)[C@H](O)[C@H](O)CO]

When R1 is a metal ion or ammonium ion in structure (a), the chemical additives have general molecular structures as listed below:

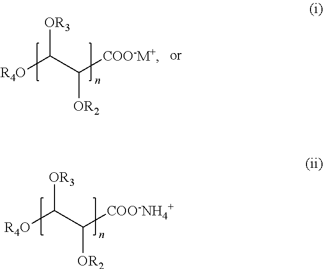

When R1 and R4 are both metal ions, or ammonium ions in structure (b), the chemical additives have general molecular structures as listed below:

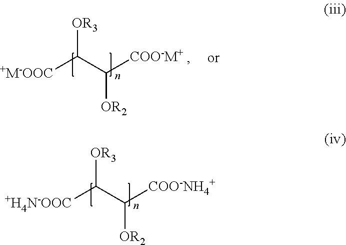

When R 1 is a metal ion and R2, R3, and R4 are all hydrogen atoms in structure (i), the molecular structures of some examples of such chemical additives are listed below:

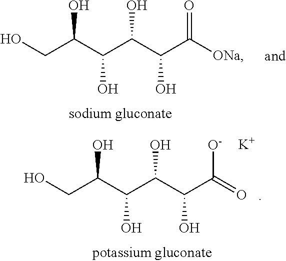

When R1 is an organic alkyl group in structure (a), the chemical additive has the organic acid ester functional group and bearing multi hydroxyl functional groups in the same molecule. The general molecular structure is shown below.

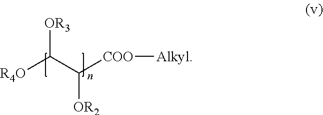

When R2, R3, and R4 are hydrogen atoms in structure (v), the molecular structures of an examples of such chemical additive is shown below:

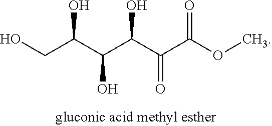 [SMILES: COC(=O)C(=O)[C@H](O)[C@@H](O)[C@H](O)CO]

The STI CMP composition contains 0.0001 wt. % to 2.0% wt. %, 0.0002 wt. % to 1.0 wt. %, 0.0003 wt. % to 0.75 wt. %, 0.0004 wt. % to 0.5 wt. %, 0.0005 wt. % to 0.5 wt. %, 0.0006 wt. % to 0.25 wt. %, or 0.0007 wt. % to 0.1 wt. % chemical additives as SiN film removal rate suppressing agents and oxide trenching dishing reducers.

The water-soluble solvent includes but is not limited to deionized (DI) water, distilled water, and alcoholic organic solvents.

The preferred water-soluble solvent is DI water.

The STI CMP composition may contain biocide from 0.0001 wt. % to 0.05 wt. %; preferably from 0.0005 wt. % to 0.025 wt. %, and more preferably from 0.001 wt. % to 0.01 wt. %.

The biocide includes, but is not limited to, Kathon™, Kathon™ CG/ICP II, from Dupont/Dow Chemical Co. Bioban from Dupont/Dow Chemical Co. They have active ingredients of 5-chloro-2-methyl-4-isothiazolin-3-one and 2-methyl-4-isothiazolin-3-one.

The STI CMP composition may contain a pH adjusting agent.

An acidic or basic pH adjusting agent can be used to adjust the STI polishing compositions to the optimized pH value.

The pH adjusting agents include, but are not limited to nitric acid, hydrochloric acid, sulfuric acid, phosphoric acid, other inorganic or organic acids, and mixtures thereof.

pH adjusting agents also include the basic pH adjusting agents, such as sodium hydride, potassium hydroxide, ammonium hydroxide, tetraalkyl ammonium hydroxide, organic quaternary ammonium hydroxide compounds, organic amines, and other chemical reagents that can be used to adjust pH towards the more alkaline direction.

The STI CMP composition contains 0 wt. % to 1 wt. %; preferably 0.01 wt. % to 0.5 wt. %; more preferably 0.1 wt. % to 0.25 wt. % pH adjusting agent.

The chemical additives used as SiN film removal rate suppressing agents and oxide trenching dishing reducers are organic carboxylic acid molecules, organic carboxylate salts or organic carboxylic ester molecules bearing multi hydroxyl functional groups in the same molecules.

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished oxide films can be Chemical vapor deposition (CVD), Plasma Enhance CVD (PECVD), High Density Deposition CVD (HDP), or spin on oxide films.

The substrate disclosed above can further comprises a silicon nitride surface. The removal selectivity of SiO₂:SiN is greater than 25, preferably greater than 30, and more preferably greater than 35.

In another aspect, there is provided a method of chemical mechanical polishing (CMP) a substrate having at least one surface comprising silicon dioxide using the chemical mechanical polishing (CMP) composition described above in Shallow Trench Isolation (STI) process. The polished oxide films can be CVD oxide, PECVD oxide, High density oxide, or Spin on oxide films.

The following non-limiting examples are presented to further illustrate the present invention.

### CMP Methodology

In the examples presented below, CMP experiments were run using the procedures and experimental conditions given below.

### Glossary

### Components

Ceria-coated Silica: used as abrasive having a particle size of approximately 100 nanometers (nm); such ceria-coated silica particles can have a particle size of ranged from approximately 20 nanometers (nm) to 500 nanometers (nm);

Ceria-coated Silica particles (with varied sizes) were supplied by JGC Inc. in Japan and were made by methods described in patent publications JP2013119131, JP2013133255, and WO 2016/159167; and patent applications JP2015-169967, and JP2015-183942.

Chemical additives, such as maltitol, D-Fructose, Dulcitol, D-sorbitol, gluconic acid, mucic acid, tartaric acid and other chemical raw materials were supplied by Sigma-Aldrich, St. Louis, Mo.

TEOS: tetraethyl orthosilicate

Polishing Pad: Polishing pad, IC1010 and other pads were used during CMP, supplied by DOW, Inc.

### Parameters

### General

Å or A: angstrom(s)—a unit of length

BP: back pressure, in psi units

CMP: chemical mechanical planarization=chemical mechanical polishing

CS: carrier speed

DF: Down force: pressure applied during CMP, units psi

min: minute(s)

ml: milliliter(s)

mV: millivolt(s)

psi: pounds per square inch

PS: platen rotational speed of polishing tool, in rpm (revolution(s) per minute)

SF: composition flow, ml/min

Wt. %: weight percentage (of a listed component)

TEOS: SiN Selectivity: (removal rate of TEOS)/(removal rate of SiN)

HDP: high density plasma deposited TEOS

TEOS or HDP Removal Rates: Measured TEOS or HDP removal rate at a given down pressure. The down pressure of the CMP tool was 2.0, 3.0 or 4.0 psi in the examples listed above.

SiN Removal Rates: Measured SiN removal rate at a given down pressure. The down pressure of the CMP tool was 3.0 psi in the examples listed.

### Metrology

Films were measured with a ResMap CDE, model 168, manufactured by Creative Design Engineering, Inc, 20565 Alves Dr., Cupertino, Calif., 95014. The ResMap tool is a four-point probe sheet resistance tool. Forty-nine-point diameter scan at 5 mm edge exclusion for film was taken.

### CMP Tool

The CMP tool that was used is a 200 mm Mirra, or 300 mm Reflexion manufactured by Applied Materials, 3050 Boweres Avenue, Santa Clara, Calif., 95054. An IC1000 pad supplied by DOW, Inc, 451 Bellevue Rd., Newark, Del. 19713 was used on platen 1 for blanket and pattern wafer studies.

The IC1010 pad or other pad was broken in by conditioning the pad for 18 mins. At 7 lbs. down force on the conditioner. To qualify the tool settings and the pad break-in two tungsten monitors and two TEOS monitors were polished with Versum® ST12305 composition, supplied by Versum Materials Inc. at baseline conditions.

### Wafers

Polishing experiments were conducted using PECVD or LECVD or HD TEOS wafers. These blanket wafers were purchased from Silicon Valley Microelectronics, 2985 Kifer Rd., Santa Clara, Calif. 95051.

### Polishing Experiments

In blanket wafer studies, oxide blanket wafers, and SiN blanket wafers were polished at baseline conditions. The tool baseline conditions were: table speed; 87 rpm, head speed: 93 rpm, membrane pressure; 2.0 psi, inter-tube pressure; 2.0 psi, retaining ring pressure; 2.9 psi, composition flow; 200 ml/min.

The composition was used in polishing experiments on patterned wafers (MIT860), supplied by SWK Associates, Inc. 2920 Scott Blvd. Santa Clara, Calif. 95054). These wafers were measured on the Veeco VX300 profiler/AFM instrument. The 3 different sized pitch structures were used for oxide dishing measurement. The wafer was measured at center, middle, and edge die positions.

TEOS: SiN Selectivity: (removal rate of TEOS)/(removal rate of SiN) obtained from the STI CMP polishing compositions were tunable.

### WORKING EXAMPLES

In the following working examples, a STI polishing composition comprising 0.2 wt. % cerium-coated silica, a biocide ranging from 0.0001 wt. % to 0.05 wt. %, and deionized water was prepared as reference (ref.).

The working polishing compositions were prepared with the reference (0.2 wt. % cerium-coated silica, a biocide ranging from 0.0001 wt. % to 0.05 wt. %, and deionized water) and a disclosed chemical additive in the range of 0.0025 wt. % to 0.015% wt. %.

### Example 1

In Example 1, the polishing compositions used were shown in Table 1. The reference sample was made using 0.2 wt. % ceria-coated silica plus very low concentration of biocide. The chemical additive, gluconic acid was used at 0.01 wt. %. Both samples have same pH values at around 5.35.

The removal rates (RR at A/min) for different films were tested. The effects of chemical additive gluconic acid on the film removal rates and selectivity were observed.

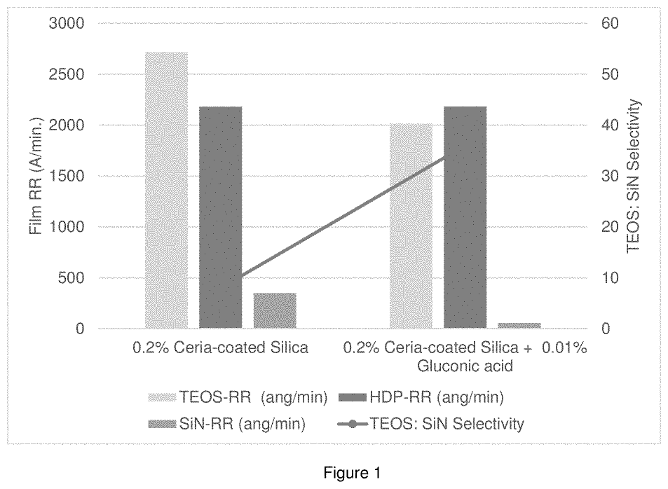

The test results were listed in Table 1 and shown in FIG. 1 respectively.

TABLE 1
Effects of Gluconic Acid on Film RR (Å/min.) & TEOS:SiN Selectivity

| | TEOS-RR | HDP-RR | SiN-RR | TEOS:SiN |
|---|---|---|---|---|
| Compositions | (ang/min) | (ang/min) | (ang/min) | Selectivity |
| 0.2% Ceria-coated Silica | 2718 | 2180 | 349 | 8:1 |
| 0.2% Ceria-coated | 2015 | 2183 | 56 | 36:1 |
| Silica + 0.01% | | | | |
| Gluconic acid | | | | |

As the results shown in Table 1 and FIG. 1, the addition of gluconic acid in the polishing composition effectively suppressed SiN removal rates while still afforded high TEOS and HDP film removal rates, and thus provided much higher TEOS: SiN film selectivity than the reference sample without using chemical additive gluconic acid.

Thus, the polishing compositions provided the suppressed SiN film removal rates and high Oxide: SiN selectivity.

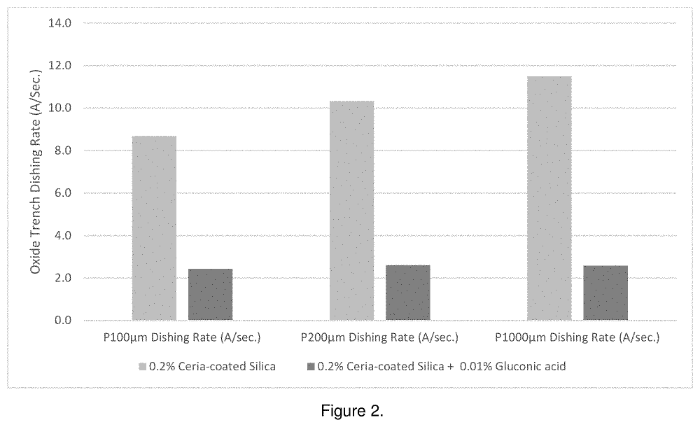

The effects of the chemical additive, gluconic acid, in the polishing composition on oxide trench dishing rates were tested. The results were listed in Table 2 and depicted in FIG. 2.

TABLE 2
Effects of Gluconic Acid on Oxide Trench Dishing Rate

| | P100 μm | P200 μm | P1000 μm |
|---|---|---|---|
| | Dishing Rate | Dishing Rate | Dishing Rate |
| Compositions | (A/sec.) | (A/sec.) | (A/sec.) |
| 0.2% Ceria-coated Silica | 8.7 | 10.3 | 11.5 |
| 0.2% Ceria-coated Silica + | 2.4 | 2.6 | 2.6 |
| 0.01% Gluconic acid | | | |

As the results shown in Table 2 and FIG. 2, the addition of the chemical additive, gluconic acid, in the polishing composition effectively reduced oxide trench dishing rates at least by >72% across different sized oxide trench features comparing with the reference sample without using gluconic acid.

The effects of addition of the chemical additive, gluconic acid, in the polishing compositions were also observed on oxide trench loss rates (A/sec.) while comparing the polishing results from the reference sample without using gluconic acid as additive.

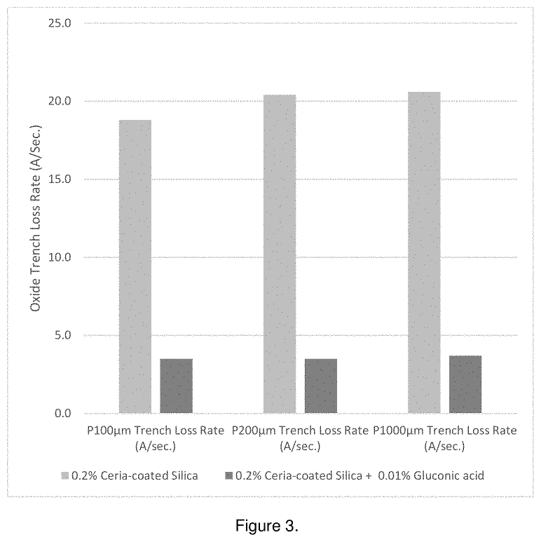

The test results were listed in Table 3 and depicted in FIG. 3 respectively.

TABLE 3
Effects of Gluconic Acid on Oxide Trench Loss Rates (A/Sec.)

| | P100 μm | P200 μm | P1000 μm |
|---|---|---|---|
| | Trench Loss | Trench Loss | Trench Loss |
| Composition | Rate (A/sec.) | Rate (A/sec.) | Rate (A/sec.) |
| 0.2% Ceria-coated Silica | 18.8 | 20.4 | 20.6 |
| 0.2% Ceria-coated Silica + | 3.5 | 3.5 | 3.7 |
| 0.01% Gluconic acid | | | |

As the results shown in Table 3 and FIG. 3, the addition of the chemical additive, gluconic acid, in the polishing composition, very effectively reduced oxide trench loss rates at least by >81% across different sized oxide trench features than the reference sample without using the chemical additive, gluconic acid.

The effects of addition of the chemical additive, gluconic acid, in the polishing compositions were also observed on oxide trench dishing vs over polishing times while comparing the polishing results from the reference sample without using gluconic acid as additive.

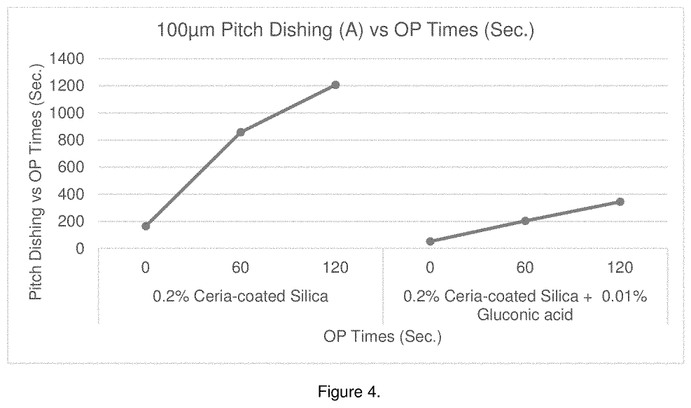

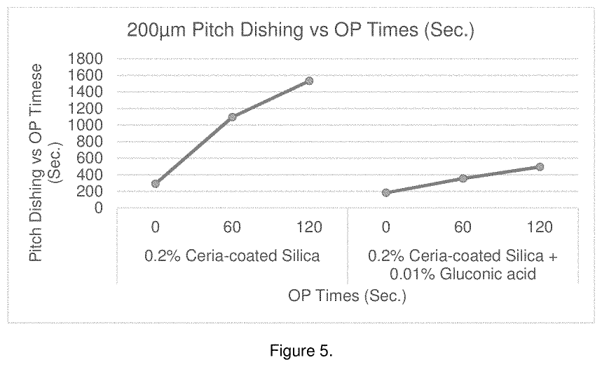

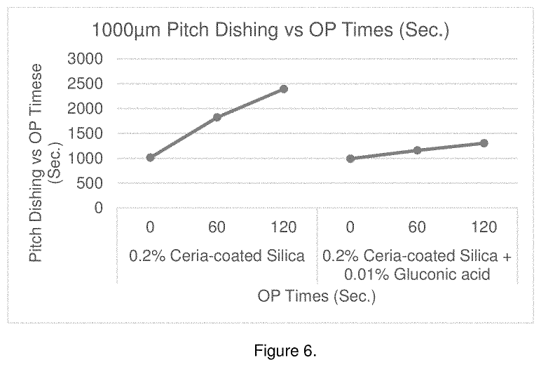

The test results on the effects of chemical additive gluconic acid in the polishing compositions on oxide trench dishing vs over polishing times were listed in Table 4, and depicted in FIG. 4, FIG. 5 and FIG. 6 respectively.

TABLE 4
Effects of Gluconic Acid on Oxide Trench Dishing vs OP Times (Sec.)

| | Polish Time | 100 μm Pitch | 200 μm Pitch | 1000 μm Pitch |
|---|---|---|---|---|
| Compositions | (Sec.) | Dishing | Dishing | Dishing |
| 0.2% Ceria-coated Silica | 0 | 165 | 291 | 1013 |
| | 60 | 857 | 1096 | 1821 |
| | 120 | 1207 | 1531 | 2392 |
| 0.2% Ceria-coated Silica + 0.01% | 0 | 52 | 182 | 992 |
| Gluconic acid | 60 | 203 | 355 | 1158 |
| | 120 | 344 | 494 | 1301 |

As the results shown in Table 4, FIG. 4, FIG. 5, and FIG. 6, the addition of the chemical additive, gluconic acid, in the polishing composition, very effectively reduced oxide trench dishing and improved over polishing stability window vs different over polishing times across different sized oxide trench features than the reference sample without using the chemical additive, gluconic acid.

Thus, the CMP composition comprised of the chemical additive suppressed SiN removal rates and increasing TEOS: SiN film selectivity, and very effectively reduced oxide trench dishing and provided improved topography on the polished patterned wafers while still afforded high TEOS and HDP film removal rates while comparing the polishing results from the reference sample without using gluconic acid as chemical additive.

### Example 2

In Example 2, the polishing composition were prepared as shown in Table 5. The chemical additive gluconic acid were used at different wt. %. pH for the compositions was all around 5.35.

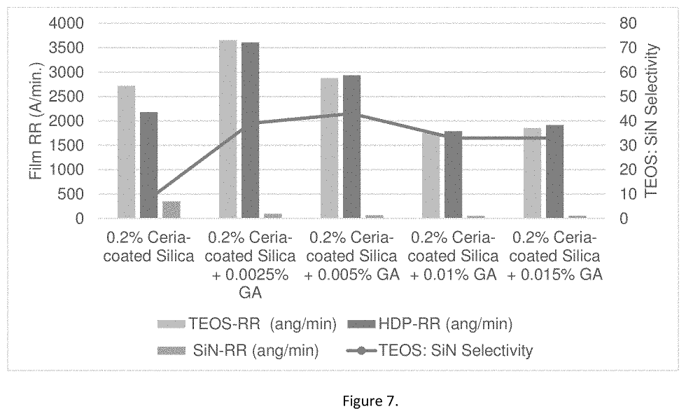

The various film polishing removal rates and TEOS: SiN selectivity results were listed in Table 5 and depicted in FIG. 7.

TABLE 5
Effects of Gluconic Acid (GA) % on Film RR (Å/min.) & TEOS:SiN Selectivity

| | TEOS-R | HDP-R | SiN-R | TEOS:SiN |
|---|---|---|---|---|
| Compositions | (ang/min) | (ang/min) | (ang/min) | Selectivity |
| 0.2% Ceria-coated Silica | 2718 | 2180 | 349 | 8:1 |
| 0.2% Ceria-coated Silica + 0.0025% GA | 3655 | 3609 | 93 | 39:1 |
| 0.2% Ceria-coated Silica + 0.005% GA | 2875 | 2932 | 67 | 43:1 |
| 0.2% Ceria-coated Silica + 0.01% GA | 1754 | 1767 | 53 | 33:1 |
| 0.2% Ceria-coated Silica + 0.015% GA | 1854 | 1914 | 57 | 33:1 |
| 0.2% Ceria-coated Silica + 0.1% GA | 110 | 91 | 49 | 2:1 |

As the results shown in Table 5 and FIG. 7, all compositions with different concentrations of gluconic acid provided a stable suppressed SiN removal rates. All compositions except the composition with 0.1 wt. % gluconic acid still afforded high TEOS and HDP film removal rates, and provided much higher TEOS: SiN film selectivity than the reference sample without using chemical additive gluconic acid. The composition with 0.1 wt. % gluconic acid suppressed the removal rates for all films tested and provided very low Oxide: SiN selectivity.

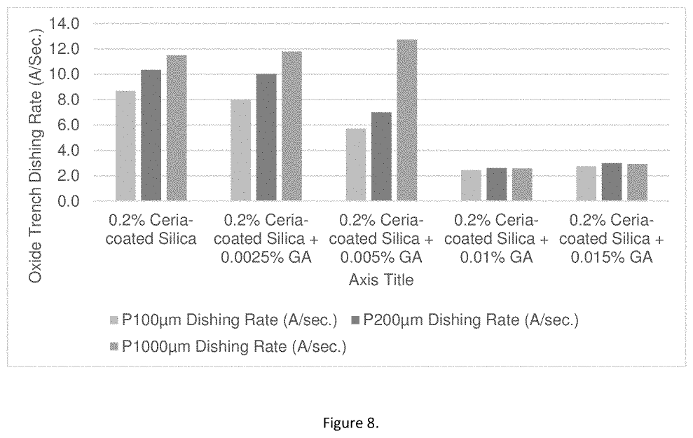

The Oxide Trench Dishing Rate using the compositions were also tested. The test results were listed in Table 6 and FIG. 8.

TABLE 6
Effects of Gluconic Acid % on Oxide Trench Dishing Rate

| | P100 μm Dishing | P200 μm Dishing | P1000 μm Dishing |
|---|---|---|---|
| Compositions | Rate (A/sec.) | Rate (A/sec.) | Rate (A/sec.) |
| 0.2% Ceria-coated Silica | 8.7 | 10.3 | 11.5 |
| 0.2% Ceria-coated Silica + 0.0025% GA | 8.0 | 10.0 | 11.8 |
| 0.2% Ceria-coated Silica + 0.005% GA | 5.7 | 7.0 | 12.7 |
| 0.2% Ceria-coated Silica + 0.01% GA | 2.4 | 2.6 | 2.6 |
| 0.2% Ceria-coated Silica + 0.015% GA | 2.7 | 3.0 | 2.9 |

As the results shown in Table 6 and FIG. 8, the addition of 0.005 wt. % gluconic acid started to reduce oxide trench dishing rates by >32% for 100 μm and 200 μm. The addition of gluconic acid at 0.01 wt. % or >0.01 wt. % concentrations very effectively reduced oxide trench dishing rates at least by >70% across different sized oxide trench features.

The effects of addition of the chemical additive, gluconic acid, used at different concentrations in the polishing compositions were also observed on oxide trench loss rates (A/sec.) while comparing the polishing results from the reference sample without using gluconic acid as additive.

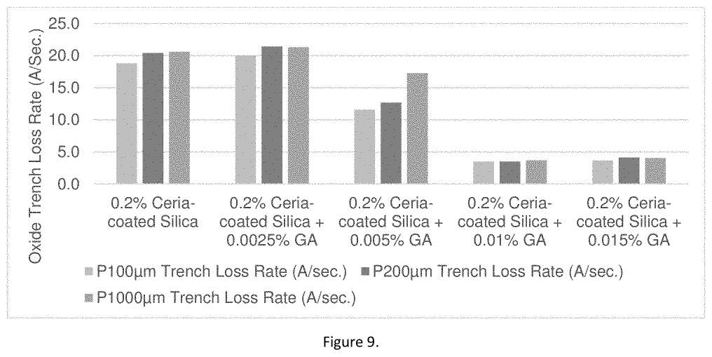

The test results were listed in Table 7 and shown in FIG. 9 respectively.

TABLE 7
Effects of Gluconic Acid % on Oxide Trench Loss Rates (A/Sec.)

| | P100 μm Trench | P200 μm Trench | P1000 μm Trench |
|---|---|---|---|
| | Loss Rate | Loss Rate | Loss Rate |
| Compositions | (A/sec.) | (A/sec.) | (A/sec.) |
| 0.2% Ceria-coated Silica | 18.8 | 20.4 | 20.6 |
| 0.2% Ceria-coated Silica + 0.0025% GA | 20.0 | 21.4 | 21.3 |
| 0.2% Ceria-coated Silica + 0.005% GA | 11.6 | 12.7 | 17.3 |
| 0.2% Ceria-coated Silica + 0.01% GA | 3.5 | 3.5 | 3.7 |
| 0.2% Ceria-coated Silica + 0.015% GA | 3.7 | 4.1 | 4.1 |

As the results shown in Table 7 and FIG. 9, the addition of 0.005 wt. % gluconic acid started to reduced oxide trench loss rates at least by >16% for 1000 μm and by 38% for 100 μm and 200 μm. The addition of gluconic acid at 0.01 wt. % or >0.01 wt. % concentrations very effectively reduced oxide trench loss rates at least by >81% across different sized oxide trench features.

The effects of addition of the chemical additive, gluconic acid, used at different concentrations in the polishing compositions were also observed on oxide trench dishing vs over polishing times while comparing the polishing results from the reference sample without using gluconic acid as additive.

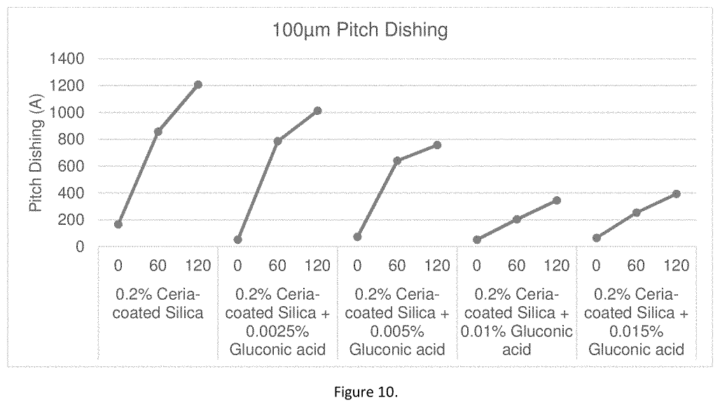

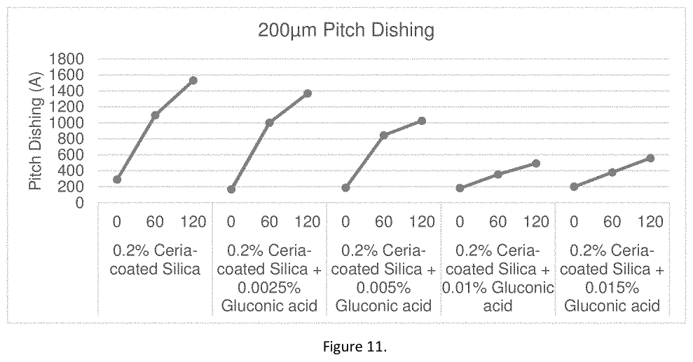

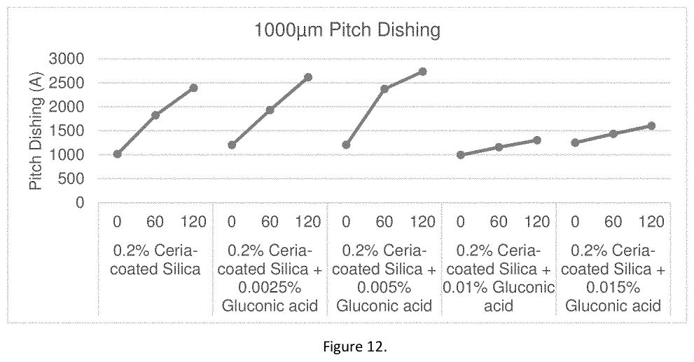

The test results were listed in Table 8 and shown in FIG. 10, FIG. 11 and FIG. 12 respectively.

TABLE 8
Effects of Gluconic Acid % on Oxide Trench Dishing vs OP Times (Sec.)

| | Over Polish | 100 um pitch | 200 um pitch | 1000 um pitch |
|---|---|---|---|---|
| Compositions | Time (Sec.) | dishing | dishing | dishing |
| 0.2% Ceria-coated Silica | 0 | 165 | 291 | 1013 |
| | 60 | 857 | 1096 | 1821 |
| | 120 | 1207 | 1531 | 2392 |
| 0.2% Ceria-coated Silica + | 0 | 51 | 167 | 1201 |
| 0.0025% Gluconic Acid | 60 | 786 | 1002 | 1932 |
| | 120 | 1012 | 1370 | 2616 |
| 0.2% 0.2% Ceria-coated Silica + | 0 | 72 | 186 | 1205 |
| 0.005% Gluconic Acid | 60 | 641 | 845 | 2371 |
| | 120 | 757 | 1026 | 2732 |
| 0.2% Ceria-coated Silica + 0.01% | 0 | 52 | 182 | 992 |
| Gluconic Acid | 60 | 203 | 355 | 1158 |
| | 120 | 344 | 494 | 1301 |
| 0.2% Ceria-coated Silica + | 0 | 65 | 200 | 1251 |
| 0.015% Gluconic Acid | 60 | 253 | 380 | 1433 |
| | 120 | 393 | 559 | 1601 |

As the results shown in Table 8, FIG. 10, FIG. 11, and FIG. 12, even with the addition of 0.0025 wt. % gluconic acid, the composition started to reduced oxide trench dishing and improved over polishing stability window. As the concentration of gluconic acid increased within the tested concentrations, the effect was more pronounced.

Again, the CMP composition comprised of the chemical additive having different testing concentrations suppressed SiN removal rates and increasing TEOS: SiN film selectivity, and very effectively reduced oxide trench dishing and provided improved topography on the polished patterned wafers while still afforded high TEOS and HDP film removal rates while comparing the polishing results from the reference sample without using gluconic acid as chemical additive.

### Example 3

In Example 3, different pH conditions were tested with gluconic acid used as chemical additive at 0.01 wt. % concentration. The tested compositions and pH conditions were listed used as in Table 9.

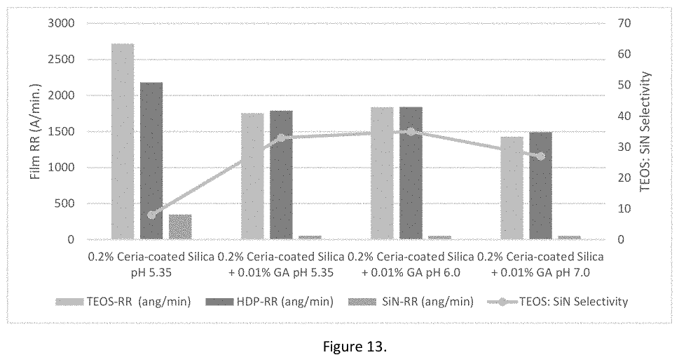

The film removal rates and TEOS: SiN selectivity were listed in Table 9 and depicted in FIG. 13.

TABLE 9
Effects of pH and 0.01 wt. % Gluconic Acid on Film RR (Å/min.)
& TEOS:SiN Selectivity

| | TEOS-RR | HDP-RR | SiN-RR | TEOS:SiN |
|---|---|---|---|---|
| Compositions | (ang/min) | (ang/min) | (ang/min) | Selectivity |
| 0.2% Ceria-coated Silica pH 5.35 | 2718 | 2180 | 349 | 8:1 |
| 0.2% Ceria-coated Silica + 0.01% GA pH 5.35 | 1754 | 1787 | 53 | 33:1 |
| 0.2% Ceria-coated Silica + 0.01% GA pH 6.0 | 1836 | 1839 | 52 | 35:1 |
| 0.2% Ceria-coated Silica + 0.01% GA pH 7.0 | 1429 | 1488 | 52 | 27:1 |

As the results shown in Table 9 and FIG. 13, the SiN film removal rates were significantly reduced by at least >82%, and TEOS: SiN selectivity were increased by at least >300% at all testing pH conditions while comparing the polishing composition without using gluconic acid as chemical additive.

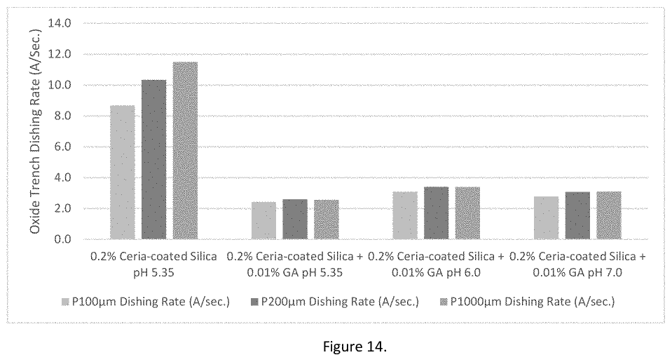

The effects of pH conditions on the composition using 0.01 wt. % gluconic acid as chemical additive on the various sized oxide trench feature dishing rates were observed and the results were listed in Table 10 and depicted in FIG. 14.

TABLE 10
Effects of pH with 0.01% Gluconic Acid on Oxide Trench Dishing Rate

| | P100 μm Dishing | P200 μm | Dishing P1000 μm |
|---|---|---|---|
| Compositions | Rate (A/sec.) | Rate (A/sec.) | Dishing Rate (A/sec.) |
| 0.2% Ceria-coated Silica pH 5.35 | 8.7 | 10.3 | 11.5 |
| 0.2% Ceria-coated Silica + 0.01% GA pH 5.35 | 2.4 | 2.6 | 2.6 |
| 0.2% Ceria-coated Silica + 0.01% GA pH 6.0 | 3.1 | 3.4 | 3.4 |
| 0.2% Ceria-coated Silica + 0.01% GA pH 7.0 | 2.8 | 3.1 | 3.1 |

As the results shown in Table 10 and FIG. 14, in general, using 0.01 wt. % gluconic acid as chemical additive in the invented polishing composition significantly reduced oxide trench dishing rates at all testing pH conditions while comparing the polishing composition without using gluconic acid as chemical additive.

The invented STI CMP polishing compositions herein can be used at the wide pH range which include acidic, neutral or alkaline.

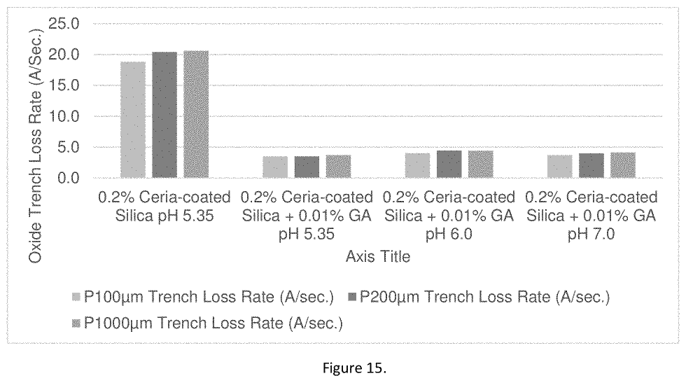

The effects of pH conditions on the composition using 0.01 wt. % gluconic acid as chemical additive on the various sized oxide trench loss rates were observed and the results were listed in Table 11 and depicted in FIG. 15.

TABLE 11
Effects of pH with 0.01% Gluconic Acid on Oxide Trench Loss Rate

| | P100 μm Trench | P200 μm Trench | P1000 μm Trench |
|---|---|---|---|
| | Loss Rate | Loss Rate | Loss Rate |
| Compositions | (A/sec.) | (A/sec.) | (A/sec.) |
| 0.2% Ceria-coated Silica pH 5.35 | 18.8 | 20.4 | 20.6 |
| 0.2% Ceria-coated Silica + 0.01% GA pH 5.35 | 3.5 | 3.5 | 3.7 |
| 0.2% Ceria-coated Silica + 0.01% GA pH 6.0 | 4.0 | 4.4 | 4.4 |
| 0.2% Ceria-coated Silica + 0.01% GA pH 7.0 | 3.7 | 4.0 | 4.1 |

As the results shown in Table 11 and FIG. 15, in general, using 0.01 wt. % gluconic acid as chemical additive in the invented polishing composition significantly reduced oxide trench loss rates at all testing pH conditions while comparing the polishing composition without using gluconic acid as chemical additive.

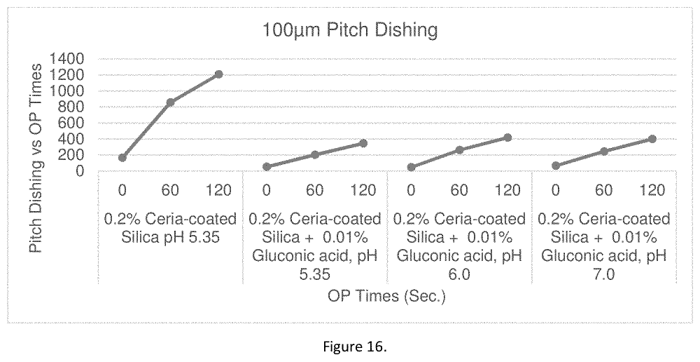

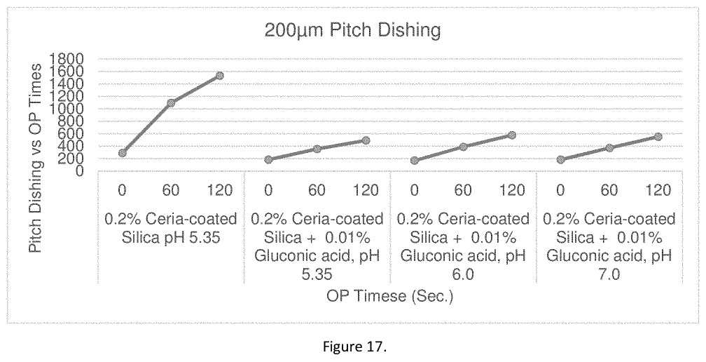

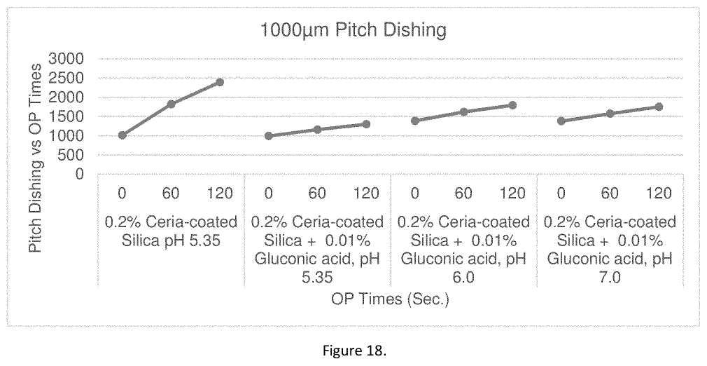

The effects of chemical additive, gluconic acid, used at 0.01 wt. % at different pH conditions in the polishing compositions were also observed on oxide trench dishing vs over polishing times while comparing the polishing results from the reference sample without using gluconic acid as additive. The test results were listed in Table 12, FIG. 16, FIG. 17 and FIG. 18 respectively.

TABLE 12
Effects of pH with 0.01% Gluconic Acid % on Oxide Trench
Dishing vs OP Times (Sec.)

| | Over Polishing | 100 μm Pitch | 200 μm Pitch | 1000 μm Pitch |
|---|---|---|---|---|
| Compositions | Times (Sec.) | Dishing | Dishing | Dishing |
| 0.2% Ceria-coated Silica pH 5.35 | 0 | 165 | 291 | 1013 |
| | 60 | 857 | 1096 | 1821 |
| | 120 | 1207 | 1531 | 2392 |
| 0.2% Ceria-coated Silica + 0.01% Gluconic | 0 | 52 | 182 | 992 |
| acid, pH 5.35 | 60 | 203 | 355 | 1158 |
| | 120 | 344 | 494 | 1301 |
| 0.2% Ceria-coated Silica + 0.01% Gluconic | 0 | 47 | 168 | 1386 |
| acid, pH 6.0 | 60 | 262 | 389 | 1618 |
| | 120 | 418 | 577 | 1794 |
| 0.2% Ceria-coated Silica + 0.01% Gluconic | 0 | 65 | 182 | 1380 |
| acid, pH 7.0 | 60 | 245 | 372 | 1575 |
| | 120 | 399 | 552 | 1753 |

As the results shown in Table 12, FIG. 16, FIG. 17, and FIG. 18, when gluconic acid is used as chemical additive at 0.01 wt. % at all testing pH conditions, the oxide trench dishing was significantly reduced, and over polishing stability window were significantly improved across different sized oxide trench features than the reference sample without using the chemical additive, gluconic acid.

### Example 4

In Example 4, gluconic acid, mucic acid or tartaric acid; ceria-coated silica composite particles were used in different compositions. A reference polishing composition without using any chemical additives was also listed. A biocide ranging from 0.0001 wt. % to 0.05 wt. %, and deionized water were also used in al compositions. The tested compositions had same pH of 5.3.

Removal rates for various film were listed in Table 13.

TABLE 13
Effects of Ceria-coated Silica Abrasives on Film RR (Å/min.)

| | TEOS-R | HDP-R | PECVD SiN-R | LPCVD SiN-R |
|---|---|---|---|---|
| Compositions | (ang/min) | (ang/min) | (ang/min) | (ang/min) |
| 0.2% Ceria-coated Silica | 2718 | 2180 | 349 | NA |
| 0.2% Ceria-coated Silica + 0.01% | 2375 | 1975 | 45 | 39 |
| Gluconic Acid | | | | |
| 0.2% Ceria-coated Silica + 0.01% Mucic | 2222 | 2216 | 46 | 33 |
| Acid | | | | |
| 0.2% Ceria-coated Silica + 0.01% Tartaric | 2251 | 2368 | 69 | 35 |
| Acid | | | | |

When gluconic acid, mucic acid or tartaric acid was used at 0.01 wt. % with ceria-coated silica as abrasives, PECVD SiN film removal rates were significantly suppressed while comparing to the PECVD SiN film removal rate obtained from the reference polishing composition not using any additive.

Such results demonstrated that these organic acids with one or two carboxyl group(s) and two or more hydroxyl groups are very effective SiN removal rate suppressing agents.

Total defect count reduction on polished TEOS and SiN wafers were tested with STI oxide polishing compositions using ceria-coated silica composite particles as abrasives.

The total defect count comparison results were listed in Table 14.

TABLE 14
Total Defect Count Comparison of Ceria-Coated Silica Based STI Oxide
Polishing Compositions

| | TEOS 0.07 um | TEOS 0.13 um | LPCVD SiN | LPCVD SiN |
|---|---|---|---|---|
| Compositions | LPD | LPD | 0.1 um LPD | 0.13 um LPD |
| 0.2% Ceria-coated Silica + 0.01% | 3042 | 915 | 3426 | 2666 |
| Gluconic Acid | | | | |
| 0.2% Ceria-coated Silica + 0.01% | 2244 | 165 | 2738 | 2104 |
| Mucic Acid | | | | |
| 0.2% Ceria-coated Silica + 0.01% | 1100 | 106 | 2890 | 1855 |
| Tartaric Acid | | | | |

As the results shown in Table 14, at the same pH conditions and with same chemical additive of gluconic acid at 0.01 wt. %, the polishing composition of using ceria-coated silica composite particles as abrasives afforded significantly lower total defect counts on both polished TEOS and SiN films.

The results shown in Table 14 also demonstrated that the polishing compositions using mucic acid or tartaric acid reduced more total defect counts than the polishing composition using gluconic acid on all test wafers.

### Example 5

In Example 5, under same pH conditions, the polishing compositions using gluconic acid, mucic acid or tartaric acid as chemical additive, were tested vs the reference polishing composition without using any chemical additives.

The tested compositions, pH conditions, HPD film removal rates, P200 trench loss rates and P200 Trench/Blanket Ratios were listed in Table 15.

TABLE 15
Effects of Chemical Additives on HDP RR, Trench Loss RR & Trench
Loss/Blanket Loss Ratio

| | P200 Trench | P200 Trench | P200 Trench/ | HDP RR(Å/ |
|---|---|---|---|---|
| Compositions | Rate (Å/sec.) | Rate (Å/min.) | Blanket Ratio | min) |
| 0.2% Ceria-coated Silica | 20.4 | 1224 | 0.42 | 2180 |
| 0.2% Ceria-coated Silica + 0.01% | 4.7 | 283 | 0.12 | 2375 |
| Gluconic Acid | | | | |
| 0.2% Ceria-coated Silica + 0.01% | | | | |
| Mucic Acid | 4.0 | 240 | 0.11 | 2222 |
| 0.2% Ceria-coated Silica + 0.01% | | | | |
| Tartaric Acid | 8.5 | 512 | 0.23 | 2251 |

As the results shown in Table 15, under the same pH conditions, the compositions using a chemical additive at same concentrations at 0.01 wt. % offered the similar HDP film removal rates, but significantly reduced trench loss rate and trench loss rate/blanket loss rate ratios comparing with the reference composition without the use of any chemical additive.

The over polishing times vs the trench dishing were tested. The results were listed in Table 16.

TABLE 16
Effects of Chemical Additives on OP Times(Sec.) vs Trench Dishing (Å)

| | | | | Blanket HDP |
|---|---|---|---|---|
| | Polish Time | 100 um pitch | 200 um pitch | RR |
| Compositions | (Sec.) | dishing | dishing | (Å/min) |
| 0.2% Ceria-coated Silica | 0 | 165 | 291 | 2180 |
| | 60 | 857 | 1096 | |
| | 120 | 1207 | 1531 | |
| 0.2% CPOP + 0.01% Gluconic Acid | 0 | 160 | 336 | 2375 |
| | 60 | 602 | 552 | |
| | 120 | 874 | 741 | |
| 0.2% CPOP + 0.01% Mucic Acid | 0 | 247 | 402 | 2222 |
| | 60 | 384 | 590 | |
| | 120 | 530 | 769 | |
| 0.2% CPOP + 0.01% Tartaric Acid | 0 | 196 | 350 | 2251 |
| | 60 | 498 | 775 | |
| | 120 | 757 | 1132 | |

As the results shown in Table 16, under the same pH conditions, the compositions using a chemical additive at same concentrations at 0.01 wt. % offered significantly lower trench dishing when 60 seconds or 120 second over polishing times were applied.

The results shown in Table 16 also demonstrated that mucic acid or gluconic acid appear to be more effective chemical additives in reducing trench dishing under different over polishing time conditions than tartaric acid as chemical additive in the polishing composition.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical mechanical polishing composition comprising:
ceria-coated inorganic oxide particles;
0.0006 wt. % to 0.25 wt. % of a chemical additive comprising at least one organic carboxylic acid group(s), at least one carboxylate salt group, or at least one carboxylic ester group; and at least two hydroxyl functional groups in the same molecule;
water soluble solvent; and
optionally
biocide;
pH adjuster;
wherein the composition has a pH of 4 to 9; and
the chemical additive has a general molecular structure of: 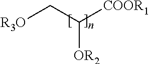
(a) or 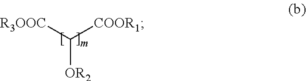
wherein n and m are independently selected from 2 to 12; R1, R2, and R3 can be the same or different atoms or functional groups and are independently selected from the group consisting of hydrogen; alkyl; alkoxy; organic group with at least one hydroxyl groups; substituted organic sulfonic acid; substituted organic sulfonic acid salt; substituted organic carboxylic acid; substituted organic carboxylic acid salt; organic carboxylic ester; organic amine group; metal ion selected from the group comprising sodium ion, potassium ion, and ammonium ion; and combinations thereof; wherein at least two of R1, R2, and R3 are hydrogen atoms.

2. The chemical mechanical polishing composition of claim 1, wherein the ceria-coated inorganic oxide particles range from 0.1 wt. % to 5 wt. % and are selected from the group consisting of ceria-coated colloidal silica, ceria-coated high purity colloidal silica, ceria-coated alumina, ceria-coated titania, ceria-coated zirconia particles and combinations thereof.

3. The chemical mechanical polishing composition of claim 1, wherein the water-soluble solvent is selected from the group consisting of deionized (DI) water, distilled water, and alcoholic organic solvents.

4. The chemical mechanical polishing composition of claim 1, wherein the chemical additive ranges from 0.0007 wt. % to 0.1 wt. %; and the composition has a pH of 4.5 to 7.5

5. The chemical mechanical polishing composition of claim 1, wherein the chemical additive is selected from the group consisting of tartaric acid, cholic acid, shikimic acid, mucic acid with two acid groups, asiatic acid, 2,2-Bis(hydroxymethyl)propionic acid, gluconic acid, sodium gluconate salt, potassium gluconate salt, gluconate ammonium salt, gluconic acid, methyl ester, and combinations thereof.

6. The chemical mechanical polishing composition of claim 1, wherein the chemical additive is selected from the group consisting of gluconic acid, gluconic acid methyl ester, gluconic acid, ethyl ester, and combinations thereof.

7. The chemical mechanical polishing composition of claim 1, wherein the composition comprises ceria-coated colloidal silica particles; the chemical additive selected from the group consisting of gluconic acid, gluconate salts, gluconic acid alkyl esters and combinations thereof; and water.

8. The chemical mechanical polishing composition of claim 1, wherein the composition further comprises at least one of
from 0.0005 wt. % to 0.025 wt. % of the biocide having active ingredients of 5-chloro-2-methyl-4-isothiazolin-3-one and 2-methyl-1-isothiazolin-3-one;
from 0.01 wt. % to 0.5 wt. % of the pH adjusting agent selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

9. A method of chemical mechanical polishing (CMP) a semiconductor substrate having at least one surface comprising silicon oxide film, comprising
providing the semiconductor substrate;
providing a polishing pad;
providing chemical mechanical polishing (CMP) composition comprising
ceria-coated inorganic oxide particles;
0.0006 wt. % to 0.25 wt. % of a chemical additive comprising at least one organic carboxylic acid group(s), at least one carboxylate salt group, or at least one carboxylic ester group; and at least two hydroxyl functional groups in the same molecule;
water soluble solvent; and
optionally
biocide;
pH adjuster;
wherein the composition has a pH of 4 to 9; and
the chemical additive has a general molecular structure of: 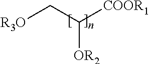
(a) or 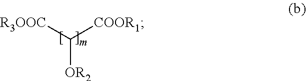
wherein n and m are independently selected from 2 to 12; R1, R2, and R3 can be the same or different atoms or functional groups and are independently selected from the group consisting of hydrogen; alkyl; alkoxy; organic group with at least one hydroxyl groups; substituted organic sulfonic acid; substituted organic sulfonic acid salt; substituted organic carboxylic acid; substituted organic carboxylic acid salt; organic carboxylic ester; organic amine group; metal ion selected from the group comprising sodium ion, potassium ion, and ammonium ion; and combinations thereof; wherein at least two of R1, R2, and R3 are hydrogen atoms;
contacting the surface of the semiconductor substrate with the polishing pad and the chemical mechanical polishing composition; and
polishing the least one surface comprising silicon dioxide.

10. The method of claim 9; wherein
the ceria-coated inorganic oxide particles range from 0.1 wt. % to 5 wt. % and are selected from the group consisting of ceria-coated colloidal silica, ceria-coated high purity colloidal silica, ceria-coated alumina, ceria-coated titania, ceria-coated zirconia particles and combinations thereof;
the water-soluble solvent is selected from the group consisting of deionized (DI) water, distilled water, and alcoholic organic solvents, and
the silicon oxide film is selected from the group consisting of Chemical vapor deposition (CVD), Plasma Enhance CVD (PECVD), High Density Deposition CVD (HDP), or spin on silicon oxide film.

11. The method of claim 9, wherein the chemical additive ranges from 0.0007 wt. % to 0.1 wt. %; and the composition has a pH of 4.5 to 7.5

12. The method of claim 9, wherein the chemical additive is selected from the group consisting of tartaric acid, cholic acid, shikimic acid, mucic acid with two acid groups, asiatic acid, 2,2-Bis(hydroxymethyl)propionic acid, gluconic acid, sodium gluconate salt, potassium gluconate salt, gluconate ammonium salt, gluconic acid, methyl ester, and combinations thereof.

13. The method of claim 9, wherein the composition comprises ceria-coated colloidal silica particles; the chemical additive ranges from 0.0007 wt. % to 0.1 wt. % and is selected from the group consisting of gluconic acid, gluconate salts, gluconic acid alkyl esters and combinations thereof; and water.

14. The method of claim 9; wherein the semiconductor substrate further comprises a silicon nitride surface; and removal selectivity of silicon oxide: silicon nitride is greater than 25.

15. A system of chemical mechanical polishing (CMP) a semiconductor substrate having at least one surface comprising silicon oxide film, comprising
a. the semiconductor substrate;
b. chemical mechanical polishing (CMP) composition comprising
1) ceria-coated inorganic oxide particles;
2) 0.0006 wt. % to 0.25 wt. % of a chemical additive comprising at least one organic carboxylic acid group(s), at least one carboxylate salt group, or at least one carboxylic ester group; and at least two hydroxyl functional groups in the same molecule;
3) water soluble solvent; and
4) optionally
5) biocide;
6) pH adjuster;
wherein the composition has a pH of 4 to 9; and
the chemical additive has a general molecular structure of: 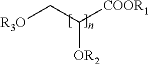
(a) or 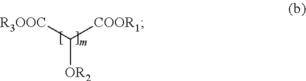
wherein n and m are independently selected from 2 to 12; R1, R2, and R3 and can be the same or different atoms or functional groups and are independently selected from the group consisting of hydrogen; alkyl; alkoxy; organic group with at least one hydroxyl groups; substituted organic sulfonic acid; substituted organic sulfonic acid salt; substituted organic carboxylic acid; substituted organic carboxylic acid salt; organic carboxylic ester; organic amine group; metal ion selected from the group comprising sodium ion, potassium ion, and ammonium ion; and combinations thereof; wherein at least two of R1, R2, and R3 are hydrogen atoms;
c. a polishing pad;
wherein the at least one surface comprising silicon oxide film is in contact with the polishing pad and the chemical mechanical polishing composition.

16. The system of claim 15; wherein
the ceria-coated inorganic oxide particles range from 0.1 wt. % to 5 wt. % and are selected from the group consisting of ceria-coated colloidal silica, ceria-coated high purity colloidal silica, ceria-coated alumina, ceria-coated titania, ceria-coated zirconia particles and combinations thereof;
the water-soluble solvent is selected from the group consisting of deionized (DI) water, distilled water, and alcoholic organic solvents, and
the silicon oxide film is selected from the group consisting of Chemical vapor deposition (CVD), Plasma Enhance CVD (PECVD), High Density Deposition CVD (HDP), or spin on silicon oxide film.

17. The system of claim 15; wherein the chemical additive ranges from 0.0007 wt. % to 0.1 wt. %; and the composition has a pH of 4.5 to 7.5

18. The system of claim 15; wherein the chemical additive is selected from the group consisting of tartaric acid, cholic acid, shikimic acid, mucic acid with two acid groups, asiatic acid, 2,2-Bis(hydroxymethyl)propionic acid, gluconic acid, sodium gluconate salt, potassium gluconate salt, gluconate ammonium salt, gluconic acid, methyl ester, and combinations thereof.

19. The system of claim 15; wherein the composition comprises ceria-coated colloidal silica particles; the chemical additive ranges from 0.0007 wt. % to 0.1 wt. % and is selected from the group consisting of gluconic acid, gluconate salts, gluconic acid alkyl esters and combinations thereof; and water.

20. The system of claim 15; wherein the semiconductor substrate further comprises a silicon nitride surface; and removal selectivity of silicon oxide: silicon nitride is greater than 25.
